(19) United States
(12) Patent Application Publication
(10) Pub. No.: US 2012/0031480 A1
(43) Pub. Date: Feb. 9, 2012

(54) Current collection system for a photovoltaic cell

(76) Inventor: Anthony C. Tisler, Troy, MI (US)

(21) Appl. No.: 12/930,863

(22) Filed: Jan. 19, 2011

Related U.S. Application Data
(60) Provisional application No. 61/296,532, filed on Jan. 20, 2010.

(51) Int. Cl. H01L 31/0224

(52) U.S. Cl. 136/256

(57) ABSTRACT

The present invention provides a photovoltaic cell having an improved current collection system. A photovoltaic cell includes a back contact substrate, a layer of photovoltaic material deposited over the back contact substrate, a front contact layer deposited over the photovoltaic material, and a current collection system. The current collection system includes a conductive wire having a loop portion. The conductive wire is attached to the front contact layer and at least one busbar. The at least one busbar is attached to end portions of the photovoltaic cell.

### CROSS REFERENCE TO RELATED APPLICATIONS

This application claims the benefit of U.S. provisional patent application No. 61/296,532 filed Jan. 20, 2010.

### FIELD OF THE INVENTION

This invention relates generally to thin-film photovoltaic (PV) devices, and more specifically to a PV cell with an improved current collection system.

### BACKGROUND OF THE INVENTION

Thin-film PV cells can be produced by forming thin-film PV semiconductor materials, such as amorphous silicon (a-Si) based thin-film material, on low-cost substrates such as glass, stainless steel, etc.

FIG. 1 illustrates an a-Si based thin-film PV cell 10 known in the art made on a metal substrate. The PV cell 10 includes the metal substrate and a back reflection layer (back reflector, BR) which covers the metal substrate. Also included in the PV cell are an a-Si based semiconductor material 12 and a transparent conductive oxide (TCO) front contact layer 14 which are disposed atop the back reflector. Finally, the PV cell includes a current collection system 16 attached to the front contact layer 14.

The current collection system 16 comprises a plurality of grid wires 18 which extend across the front contact layer 14. Each grid wire 18 has a first end 20 and a second end 22 which terminate on busbars 24. However, the connection area 23 between the grid wires 18 and the busbars 24 is small which may lead to a decrease in cell efficiency or cell failure.

Therefore, a need exists for a PV cell that has increases the connection area between the grid wire and the busbars.

### BRIEF DESCRIPTION OF THE DRAWINGS

FIG. 1 is a top view of an embodiment of a PV cell known in the art;

FIG. 2 is a top view of an embodiment of a PV cell the present invention;

FIG. 3 is a top view of an embodiment of a PV cell the present invention; and

FIG. 4 is a top view of an embodiment of a PV cell the present invention.

### DETAILED DESCRIPTION OF THE PREFERRED EMBODIMENT(S)

It is to be understood that the invention may assume various alternative orientations and step sequences, except where expressly stated to the contrary. It should also be appreciated that the specific embodiments and processes illustrated in and described in the following specification are simply exemplary embodiments of the inventive concepts defined in the appended claims. For example, although the present invention will be described in connection with a-Si the present invention is not so limited. As such, the present invention may also be applied to PV cell having at least one single junction (SJ) of cadmium telluride (CdTe), amorphous silicon germanium (a-SiGe), crystalline silicon (c-Si), microcrystalline silicon (μc-Si), nanocrystalline silicon (nc-Si), CIS₂, or CIGS. Additionally, although the present invention will be described with a substrate it should be appreciated that it may also be utilized in connection with a superstrate.

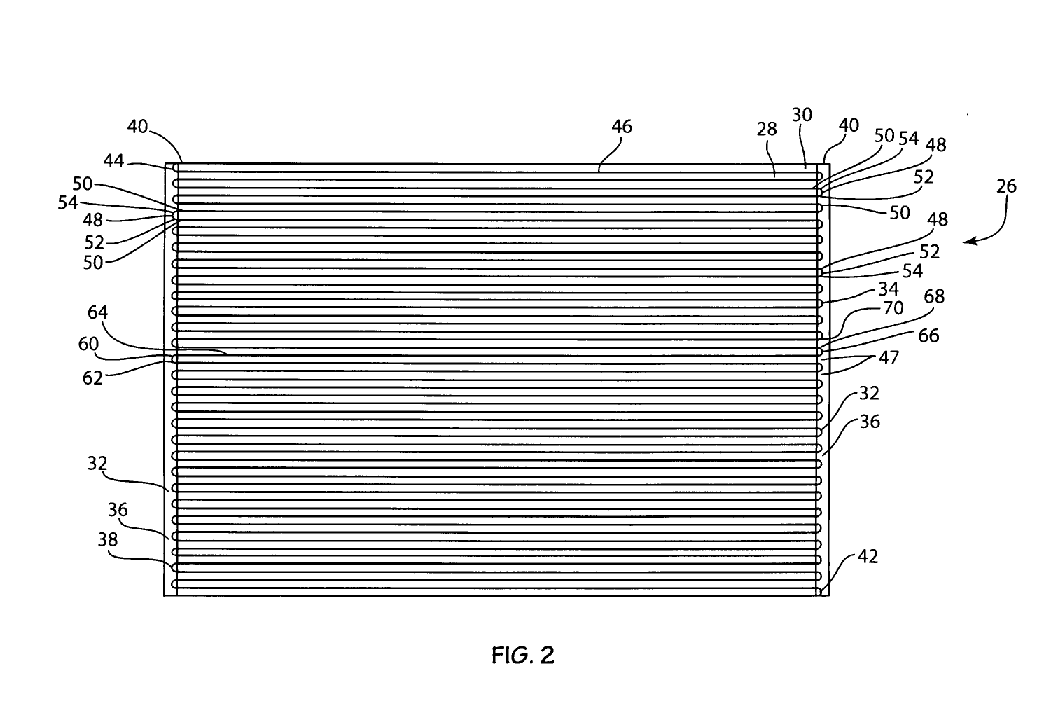

FIG. 2 illustrates a thin-film PV cell 26, preferably an a-Si based, of the present invention. In an embodiment, the PV cell 26 comprises a metallic substrate (not depicted) such as a stainless steel foil, for an electric back contact substrate, a back reflector (not depicted), a layer of photovoltaic material 28 such as an a-Si based PV semiconductor material deposited over the back contact substrate, and a transparent and conductive front contact layer 30 such as a TCO front contact layer, and a current collection system 32.

The current collection system 32 comprises a wire grid 34 and at least one busbar 36, preferably a pair of busbars 36. In an embodiment, the wire grid 34 comprises a conductive wire 38. In this embodiment, the conductive wire 38 is attached to the front contact layer 30 and the at least one busbar 36. The at least one busbar 36 is attached to a side portion 40 of the PV cell 26.

The conductive wire 38 may have a lower resistance than the front contact layer 30. In this embodiment, the conductive wire 38 may be metallic, for example silver, copper, or a combination thereof. In another embodiment, the conductive wire 38 comprises a metal core wire and a carbon coating covering the metal core wire. Examples of the conductive wire 38 of this embodiment can be found in U.S. Pat. Nos. 5,861,324 and 5,681,402, the disclosures of which are fully incorporated by reference. It should also be appreciated that other conductive wire materials and configurations are compatible with the present invention.

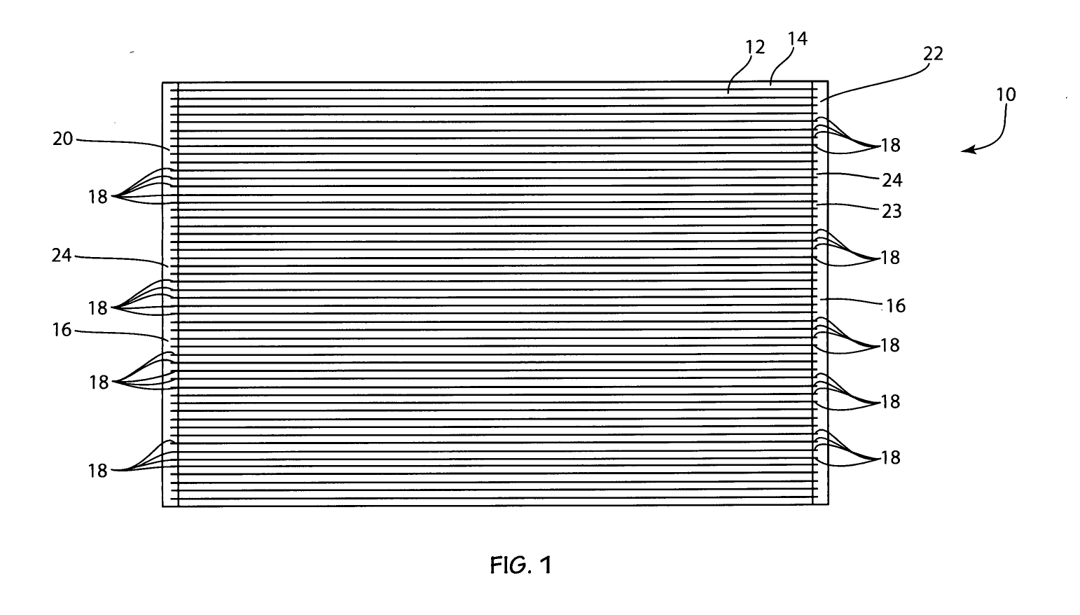

As shown in FIG. 2, the conductive wire 38 comprises a first end 42, a second end 44, and portions 46 which extend across the PV cell 26. In an embodiment, the conductive wire 38 is unbroken over the cell. Thus, in contrast to the plurality of grid wires 18 depicted in FIG. 1, the conductive wire 38 of the present invention makes more than one pass across the front contact layer 30. As such, a single conductive wire may provide all of the current collection for the PV cell front contact layer 30. In an embodiment, each pass of the conductive wire 38 is equally spaced apart on the front contact layer 30.

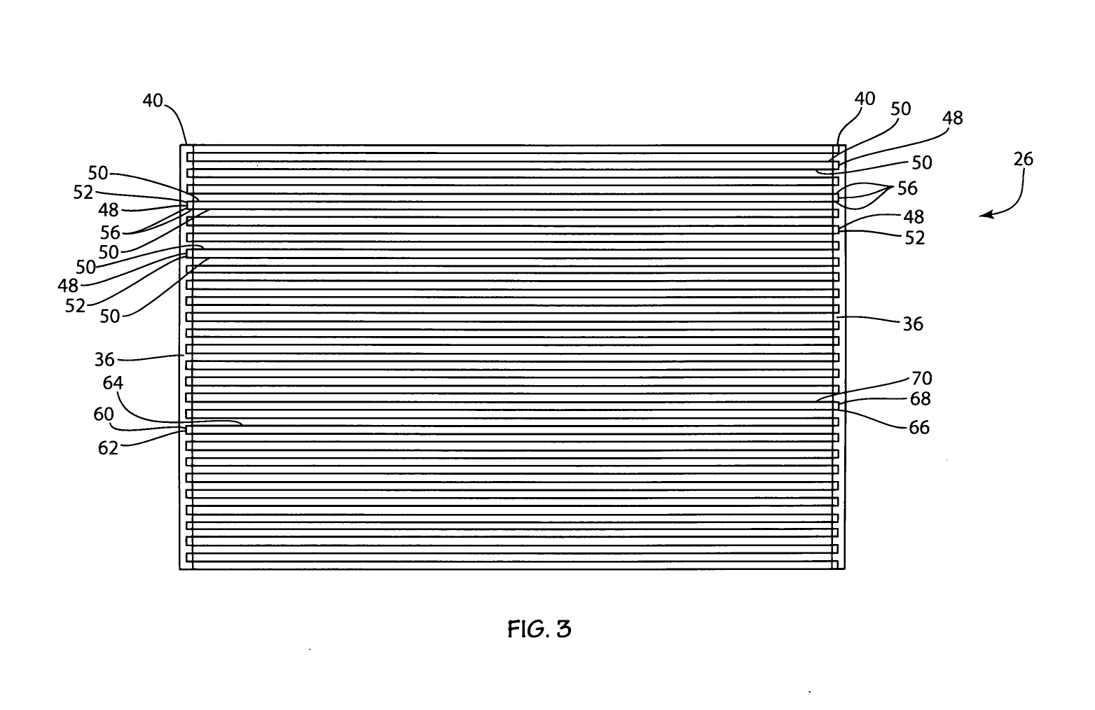

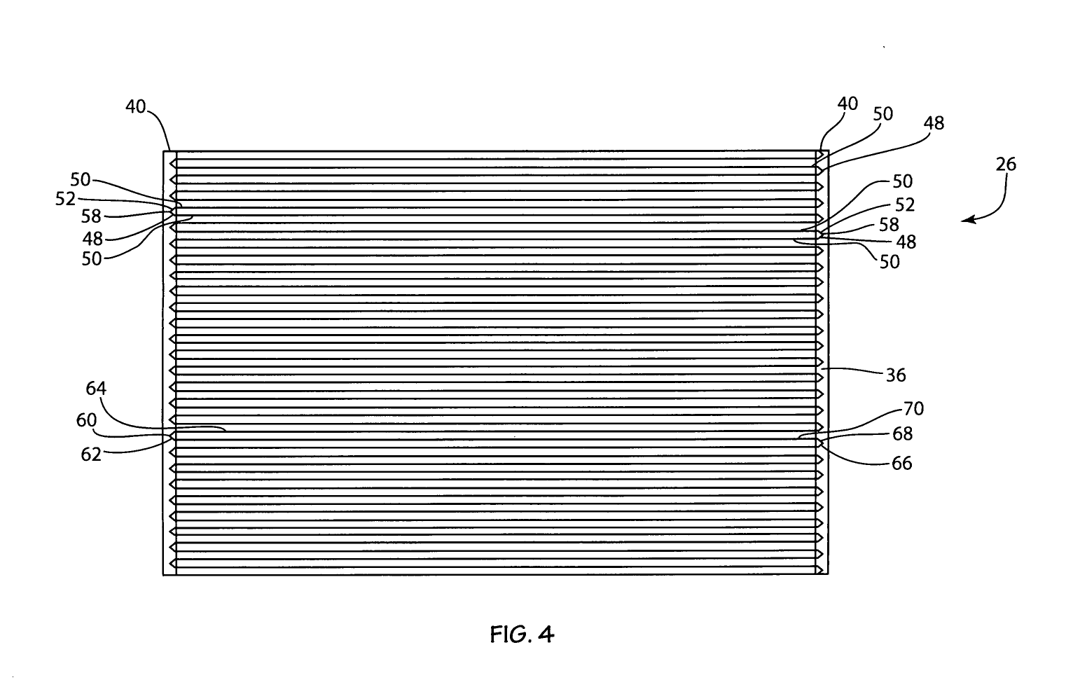

The present invention also provides a current collection system 32 with an improved connection area 47 between the wire grid 34 and the at least one busbar 36. As shown in FIGS. 2-4, in an embodiment a portion of the conductive wire 38 comprises a loop portion 48. In another embodiment, the conductive wire comprises a plurality of loop portions 48. Each loop portion 48 is connected to two conductive wire portions 50 which extend across the PV cell 26. Additionally, each loop portion 48 has an end portion 52 which allows the conductive wire 38 to double over on itself. As depicted in FIG. 2, in an embodiment the loop portions 48 may have a semicircular end portion 54. As shown in FIG. 3, in another embodiment the loop portions 48 may have an end portion 52 with perpendicular portions 56. As shown in FIG. 4, in yet another embodiment the loop portions 48 may have an end portion 52 having an angle 58 which is less than 90 degrees. In an alternative embodiment (not depicted), the loop portions 48 may have an end portion 52 having an angle which is greater than 90 degrees. It should also be noted that the embodiments of the end portions 52 described above may be combined and incorporated within a PV cell 26.

Each loop portion 48 is attached to a busbar 36. Thus, in an embodiment a first portion 60 of the conductive wire 38 forms a loop portion 62 adjacent the PV cell side portion 40, a second portion 64 of the conductive wire 38 extends across the PV cell 26, a third portion 66 of the conductive wire 38 forms a loop portion 68 adjacent the PV cell side portion 40, and a fourth portion 70 of the conductive wire 38 extends across the PV cell 26. In this embodiment, the conductive wire fourth portion 70 is in a parallel spaced apart relationship with the conductive wire second portion 64. Therefore, in this embodiment, the conductive wire first portion 60 and third portion 66 are each attached to a busbar 36.

The conductive wire loop portions 48 and the conductive wire's parallel spaced apart relationship may be formed by using a wiring frame.

The above detailed description of the present invention is given for explanatory purposes. Thus, it will be apparent to those skilled in the art that numerous changes and modifications can be made without departing from the scope of the invention. Accordingly, the whole of the foregoing description is to be construed in an illustrative and not a limitative sense. Therefore, specific dimensions, directions or other physical characteristics relating to the embodiments disclosed are not to be considered as limiting, unless the claims expressly state otherwise.

I claim:

1. A photovoltaic cell, comprising:
a back contact substrate;
a layer of photovoltaic material deposited over the back contact substrate;
a front contact layer deposited over the photovoltaic material;
a current collection system comprising a conductive wire attached to the front contact layer and at least one busbar attached to side portions of the photovoltaic cell and the conductive wire, wherein the conductive wire comprises a loop portion.

2. The photovoltaic cell of claim 1, wherein the conductive wire extends across the photovoltaic cell.

3. The photovoltaic cell of claim 1, wherein the conductive wire comprises a plurality of loop portions.

4. The photovoltaic cell of claim 1, wherein the conductive wire provides all of the current collection for the front contact layer.

5. The photovoltaic cell of claim 1, wherein the conductive wire makes more than one pass across the front contact layer.

6. The photovoltaic cell of claim 1, wherein the conductive wire is metallic.

7. The photovoltaic cell of claim 1, wherein the conductive wire comprises a metal core wire and a carbon coating covering the metal core wire.

8. The photovoltaic cell of claim 1, wherein the conductive wire is equally spaced apart on the front contact layer.

9. The photovoltaic cell of claim 1, wherein the conductive wire loop portion is attached to the busbar.

10. The photovoltaic cell of claim 4, wherein the conductive wire is unbroken having only a first end and a second end.

11. A photovoltaic cell, comprising:
a back contact substrate;
a layer of photovoltaic material deposited over the back contact substrate;
a front contact layer deposited over the photovoltaic material;
a current collection system comprising a conductive wire attached to the front contact layer and a pair of busbars attached to side portions of the photovoltaic cell and the conductive wire, wherein a first portion of the conductive wire forms a loop portion adjacent a side portion of the photovoltaic cell, a second portion of the conductive wire extends across the photovoltaic cell, a third portion of the conductive wire forms a loop portion adjacent a side portion of the photovoltaic cell, and a fourth portion of the conductive wire extends across the photovoltaic cell in a parallel spaced apart relationship with the second portion of the conductive wire.

12. The photovoltaic cell of claim 11, wherein the conductive wire first and third portions are each attached to a busbar of the pair of busbars.
